(19) United States
(12) Patent Application Publication
(10) Pub. No.: US 2026/0076191 A1
(43) Pub. Date: Mar. 12, 2026

(54) LAMINATED SUBSTRATE

(71) Applicant: NGK INSULATORS, LTD., Nagoya-City (JP)

(72) Inventors: Morimichi WATANABE, Nagoya-Shi (JP); Ayumi SUZUKI, Ama-Gun (JP); Takahiro TOMITA, Chita-Shi (JP)

(73) Assignee: NGK INSULATORS, LTD., Nagoya-City (JP)

(21) Appl. No.: 19/387,821

(22) Filed: Nov. 13, 2025

Related U.S. Application Data
(63) Continuation of application No. PCT/JP2024/019265, filed on May 24, 2024.

(30) Foreign Application Priority Data
Jun. 1, 2023 (JP) 2023-090896

(51) Int. Cl. H01L 23/373

(52) U.S. Cl. CPC H10W 40/254; H10W 40/255

(57) ABSTRACT

There is provided a laminated substrate including a three-layer structure composed of: a device substrate, which is composed of at least one single crystal material selected from the group consisting of Si, SiC, GaN, AlN, BN, Ga₂O₃, Cr₂O₃, LiTaO₃, and LiNbO₃; a metal layer on the device substrate; and a diamond layer on the metal layer.

### CROSS-REFERENCE TO RELATED APPLICATIONS

This application is a continuation application of PCT/JP2024/019265 filed May 24, 2024, which claims priority to Japanese Patent Application No. 2023-090896 filed Jun. 1, 2023, the entire contents all of which are incorporated herein by reference.

### BACKGROUND OF THE INVENTION

### 1. Field of the Invention

The present disclosure relates to a laminated substrate.

### 2. Description of the Related Art

Diamond is a material having an extremely high thermal conductivity (about 22 W/cm·K), and application of diamond to a heat sink or the like of a device such as a semiconductor device is expected. The application to a purpose such as a heat sink requires a diamond film or substrate of a certain size.

As a method for producing a diamond substrate, Non-Patent Literature 1 (Makoto Kasu, Ryota Takaya, and Seong-Woo Kim, Diamond & Related Materials 126 (2022) 109086) discloses that a laminate of sapphire/Ir buffer layer/diamond layer was produced by depositing an Ir buffer layer with a thickness of 1 μm on a sapphire substrate by sputtering, performing diamond nucleation on the Ir buffer layer through the bias-enhanced nucleation (BEN) process using a DC plasma CVD apparatus, and growing a diamond layer on the BEN-treated Ir buffer layer by microwave plasma CVD. This literature also discloses that a microneedle process is essential for obtaining a free-standing diamond layer from the laminate without breakage.

### CITATION LIST

### Non-Patent Literature

Non-Patent Literature 1: Makoto Kasu, Ryota Takaya, and Seong-Woo Kim, “Growth of high-quality inch-diameter heteroepitaxial diamond layers on sapphire substrates in comparison to MgO substrates”, Diamond & Related Materials 126 (2022) 109086

### SUMMARY OF THE INVENTION

As described above, a technique for producing a free-standing diamond substrate or film (hereinafter collectively referred to as a diamond substrate) is known. In the case where a free-standing diamond substrate is applied as a heat sink or the like to a device such as a semiconductor device, it is conceivable to directly join the diamond substrate to the device. However, both the diamond substrate and the device are required to be mirror-finished, which increases the cost.

The present inventors have recently found that a laminated substrate for a device including a heat sink material having good thermal conductivity can be provided at low cost by forming a diamond layer above a predetermined device substrate with a metal layer interposed therebetween.

An object of the present disclosure is therefore to provide a laminated substrate for a device including a heat sink material having good thermal conductivity at low cost.

The present disclosure provides the following aspects.

### [Aspect 1]

A laminated substrate comprising a three-layer structure composed of:
a device substrate, which is composed of at least one single crystal material selected from the group consisting of Si, SiC, GaN, AlN, BN, Ga₂O₃, Cr₂O₃, LiTaO₃, and LiNbO₃;
a metal layer on the device substrate; and
a diamond layer on the metal layer.

### [Aspect 2]

The laminated substrate according to aspect 1, wherein the device substrate is composed of at least one single crystal material selected from the group consisting of Si and SiC.

### [Aspect 3]

The laminated substrate according to aspect 1 or 2, wherein the device substrate is composed of at least one single crystal material selected from the group consisting of GaN, AlN, and BN.

### [Aspect 4]

The laminated substrate according to any one of aspects 1 to 3, wherein the device substrate is composed of at least one single crystal material selected from the group consisting of Ga₂O₃, Cr₂O₃, LiTaO₃, and LiNbO₃.

### [Aspect 5]

The laminated substrate according to any one of aspects 1 to 4, wherein the metal layer is composed of a metal or alloy comprising at least one selected from the group consisting of Ir, Rh, Pt, Ru, and Au.

### [Aspect 6]

The laminated substrate according to any one of aspects 1 to 4, wherein the metal layer is composed of a metal or alloy comprising at least one selected from the group consisting of Ni, Cu, Fe, and Co.

### [Aspect 7]

The laminated substrate according to any one of aspects 1 to 4, wherein the metal layer is composed of a metal or alloy comprising Be.

### [Aspect 8]

The laminated substrate according to any one of aspects 1 to 4, wherein the metal layer is composed of a metal or alloy comprising Ir.

### [Aspect 9]

The laminated substrate according to any one of aspects 1 to 8, wherein the diamond layer is composed of a diamond single crystal.

### [Aspect 10]

The laminated substrate according to any one of aspects 1 to 9, wherein the diamond layer is composed of a biaxially oriented layer of diamond.

### [Aspect 11]

The laminated substrate according to any one of aspects 1 to 10, wherein the diamond layer is composed of a uniaxially oriented layer of diamond.

### [Aspect 12]

The laminated substrate according to any one of aspects 1 to 11, wherein the device substrate has a thickness of 1 μm to 30 μm.

### [Aspect 13]

The laminated substrate according to any one of aspects 1 to 12, wherein the metal layer has a thickness of 50 nm to 100 μm.

### [Aspect 14]

The laminated substrate according to any one of aspects 1 to 13, wherein the diamond layer has a thickness of 100 μm to 2.0 mm.

### [Aspect 15]

The laminated substrate according to any one of aspects 1 to 14, wherein a thickness Ts of the device substrate, a thickness Tm of the metal layer, and a thickness Td of the diamond layer satisfy relationships Td≥Ts×10 and Td≥Tm×10.

### [Aspect 16]

The laminated substrate according to any one of aspects 1 to 14, wherein a thickness Ts of the device substrate, a thickness Tm of the metal layer, and a thickness Td of the diamond layer satisfy relationships Ts≥Tm×10 and Ts≥Td×10.

### [Aspect 17]

The laminated substrate according to any one of aspects 1 to 14, wherein a thickness Ts of the device substrate, a thickness Tm of the metal layer, and a thickness Td of the diamond layer satisfy relationships Tm≥Ts×10 and Tm≥Td×10.

### [Aspect 18]

The laminated substrate according to any one of aspects 1 to 14, wherein a thickness Ts of the device substrate, a thickness Tm of the metal layer, and a thickness Td of the diamond layer satisfy relationships Ts≥Tm×10 and Td≥Tm×10.

### [Aspect 19]

The laminated substrate according to any one of aspects 1 to 4, 7, and 9 to 18, wherein the metal layer is a film composed of a metal or alloy comprising Be deposited by sputtering.

### BRIEF DESCRIPTION OF THE DRAWINGS

FIG. 1 is a schematic sectional view of a laminated substrate according to one aspect of the present disclosure.

FIG. 2 is a schematic sectional view of a laminated substrate according to a preferable aspect of the present disclosure.

FIG. 3 is a schematic sectional view of a laminated substrate according to another preferable aspect of the present disclosure.

FIG. 4 is a schematic sectional view of a laminated substrate according to still another preferable aspect of the present disclosure.

FIG. 5 is a schematic sectional view of a laminated substrate according to still another preferable aspect of the present disclosure.

### DETAILED DESCRIPTION OF THE INVENTION

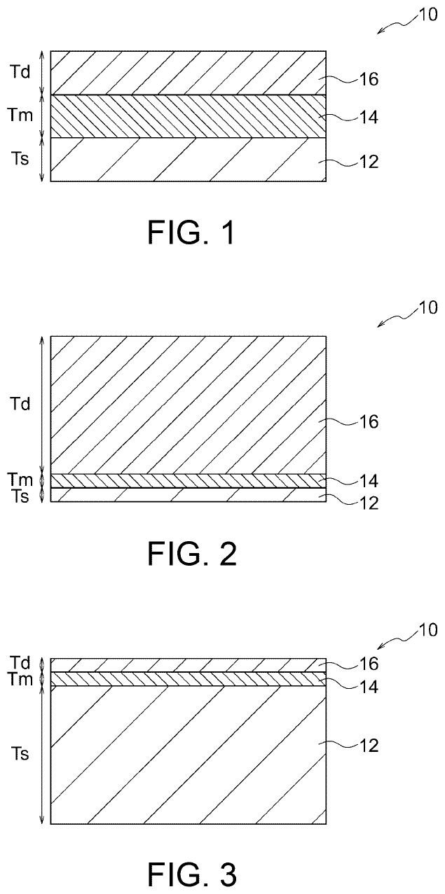

FIG. 1 shows a laminated substrate 10 according to one aspect of the present disclosure. The laminated substrate 10 includes a three-layer structure composed of a device substrate 12 (i.e., a substrate 12 for a device), a metal layer 14, and a diamond layer 16. The device substrate 12 is composed of at least one single crystal material selected from the group consisting of Si, SiC, GaN, AlN, BN, Ga₂O₃, Cr₂O₃, LiTaO₃, and LiNbO₃. The metal layer 14 is disposed on the device substrate 12. The diamond layer 16 is disposed on the metal layer 14. A laminated substrate 10 for a device including a heat sink material having good thermal conductivity can be provided at low cost by forming the diamond layer 16 above the predetermined device substrate 12 with the metal layer 14 interposed therebetween as described above.

As described above, in the case where a free-standing diamond substrate is applied as a heat sink or the like to a device such as a semiconductor device, it is conceivable to directly join the diamond substrate to the device. However, both the diamond substrate and the device are required to be mirror-finished, which increases the cost. In this respect, the present disclosure eliminates the need to produce a free-standing diamond substrate and therefore to directly join the diamond substrate to the device, so that the laminated substrate 10 for a device including a heat sink material having good thermal conductivity can be provided at low cost. In addition, when a product obtained by directly joining a diamond single crystal substrate to a device substrate is heated to deposit a functional layer, the product may get greatly warped. As a result, the functional layer cannot be deposited, or (although the functional layer can be deposited) the quality of the functional layer can be deteriorated. In this respect, the laminate of the present disclosure is expected to reduce the warping of the laminated substrate when heated.

The device substrate 12 is composed of at least one single crystal material selected from the group consisting of Si, SiC, GaN, AlN, BN, Ga₂O₃, Cr₂O₃, LiTaO₃, and LiNbO₃. In a preferable aspect of the present disclosure, the single crystal material composing the device substrate 12 is at least one selected from the group consisting of Si and SiC. In another preferable aspect of the present disclosure, the single crystal material composing the device substrate 12 is at least one selected from the group consisting of GaN, AlN, and BN. In still another preferable aspect of the present disclosure, the single crystal material composing the device substrate 12 is at least one selected from the group consisting of Ga₂O₃, Cr₂O₃, LiTaO₃, and LiNbO_{3.}

The thickness of the device substrate 12 is not particularly limited but is preferably 1 μm to 2.0 mm. The device substrate 12 may be in the form of a thin film as a functional layer. In this case, the thickness of the device substrate 12 is more preferably 1 μm to 30 μm, still more preferably 1 μm to 10μm. On the other hand, in the case where the device substrate 12 is used as a supporting substrate configured to support the three-layer structure, the thickness of the device substrate 12 is preferably 100 μm to 2,000 μm, more preferably 300 μm to 1,300 μm, particularly preferably 350 μm to 1,000 μm.

A commercially available single crystal substrate may be used for the device substrate 12, and the method for producing the substrate is not particularly limited. The device substrate 12 may be provided with a functional layer formed thereon, or may be in the form of an independent substrate 12 before the functional layer is formed. Examples of the functional layer include a p-type layer, an n-type layer, a drift layer, and a buffer layer. A device may be further mounted on the device substrate 12 or the functional layer. The laminated substrate 10 of the present disclosure may therefore be a substrate on which a device has been mounted or may be a substrate before a device is mounted. That is, the laminated substrate 10 may consist of the three-layer structure composed of the device substrate 12, the metal layer 14, and the diamond layer 16, or may be further provided with the functional layer and/or device on the device substrate 12 in addition to the three-layer structure. Examples of the device include a semiconductor device and a piezoelectric element, preferably a semiconductor device.

The metal layer 14 is not particularly limited but is preferably composed of a metal or alloy including Ir, Rh, Pt, Ru, Au, Ni, Cu, Fe, Co, and Be. In a preferable aspect of the present disclosure, the metal or alloy composing the metal layer 14 includes at least one selected from the group consisting of Ir, Rh, Pt, Ru, and Au, and includes, for example, Ir. In another preferable aspect of the present disclosure, the metal or alloy composing the metal layer 14 includes at least one selected from the group consisting of Ni, Cu, Fe, Co, and Be, and includes, for example, Be.

The thickness of the metal layer 14 is not particularly limited but is preferably 50 nm to 1 mm, more preferably 50 nm to 100 μm, still more preferably 100 nm to 100 μm.

The metal layer 14 may be formed on the device substrate 12 by a known deposition technique such as chemical vapor deposition (CVD) or physical vapor deposition (PVD), and the method is not particularly limited. Examples of the technique for depositing the metal layer 14 include sputtering and atomic layer deposition (ALD).

The diamond layer 16 is composed of diamond. The diamond may be monocrystalline or polycrystalline but is preferably composed of a biaxially oriented layer or uniaxially oriented layer of diamond. If the diamond layer 16 is composed of a biaxially oriented layer or uniaxially oriented layer, reduction of the warping of the laminated substrate 10 having the three-layer structure is facilitated. That is, the diamond layer 16 may be composed of a diamond single crystal, a biaxially oriented layer of diamond, or a uniaxially oriented layer of diamond.

The biaxially oriented layer of diamond is preferably oriented in terms of the c-axis direction and the a-axis direction. The biaxially oriented layer may be a diamond single crystal, a diamond polycrystal, or a mosaic crystal as long as the biaxially oriented layer is c-axis and a-axis oriented. The mosaic crystal refers to an aggregate of crystals in which the crystal orientations are slightly different in terms of one or both of the c-axis and the a-axis while there is no clear grain boundary. The method for evaluating the orientation is not particularly limited, and a known analytical approach such as the electron backscatter diffraction patterns (EBSD) method or the X-ray pole figure can be used. For example, in the case where the EBSD method is used, an inverse pole figure map of the surface (plate surface) or a section orthogonal to the plate surface of the biaxially oriented layer is measured. The orientation in two axes; the substantial normal direction and the substantial plate surface direction, is defined to be satisfaction of the following four requirements in the obtained inverse pole figure map: (A) orientation in a particular orientation (first axis) in the substantial normal direction of the plate surface is achieved, (B) orientation in a particular orientation (second axis) in a substantial in-plate-surface direction orthogonal to the first axis is achieved, (C) the inclination angles with respect to the first axis are distributed within ±10°, and (D) the inclination angles with respect to the second axis are distributed within ±10°. In other words, when the above four requirements are satisfied, orientation in terms of two axes; the c-axis and the a-axis, is judged to be true. For example, when the substantial normal direction of the plate surface is c-axis oriented, it is sufficient that the substantial in-plate-surface direction is oriented in terms of a particular orientation (such as the a-axis) orthogonal to the c-axis. It is sufficient that the biaxially oriented layer is oriented in terms of two axes; the substantial normal direction and the substantial in-plate-surface direction, but the substantial normal direction is preferably c-axis oriented. The mosaic property of the biaxially oriented layer decreases as the inclination angle distribution in the substantial normal direction and/or the substantial in-plate-surface direction decreases, and the crystal becomes close to a single crystal as the inclination angle distribution approaches zero. In the viewpoint of the crystallinity of the biaxially oriented layer, the inclination angle distribution is therefore preferably small in both the substantial normal direction and the substantial plate surface direction, more preferably, for example, ±5° or less, still more preferably ±3° or less.

The uniaxially oriented layer of diamond is preferably oriented in terms of the c-axis direction or a-axis direction. The method for evaluating the orientation is not particularly limited, and a known analytical approach such as the electron backscatter diffraction patterns (EBSD) method or the X-ray pole figure can be used. For example, in the case where the EBSD method is used, an inverse pole figure map of the surface (plate surface) or a section orthogonal to the plate surface of the uniaxially oriented layer is measured to judge the orientation.

The thickness of the diamond layer 16 is not particularly limited but is preferably 1 μm or more, more preferably 20 μm or more, still more preferably 100 μm to 2.0 mm.

The diamond layer 16 may be formed on the metal layer 14 by a known deposition technique such as chemical vapor deposition (CVD) or physical vapor deposition (PVD), and the method is not particularly limited. For example, as disclosed in Non-Patent Literature 1, diamond nucleation may be performed on the metal layer 14 (such as the Ir layer) through the bias-enhanced nucleation (BEN) process using a DC plasma CVD apparatus to grow the diamond layer 16 on the BEN-treated metal layer 14 by microwave plasma CVD. For example, the growth of the diamond layer 16 by microwave plasma CVD can be performed at a substrate temperature of 1,000° C. using CH₄ diluted with H₂ as a carbon source gas.

In the laminated substrate 10, any of the device substrate 12, the metal layer 14, and the diamond layer 16 may have the function of supporting the three-layer structure (function as a supporting matrix). In other words, the thickest layer in the three-layer structure may be any of the device substrate 12, the metal layer 14, and the diamond layer 16.

In a preferable aspect of the present disclosure, the diamond layer 16 can have the function of supporting the three-layer structure. In this case, as shown in FIG. 2, a thickness Ts of the device substrate 12, a thickness Tm of the metal layer 14, and a thickness Td of the diamond layer 16 preferably satisfy the relationships Td≥Ts×10 and Td≥Tm×10, more preferably Td≥Ts×20 and Td≥Tm×20. The upper limit of Td is not particularly limited but preferably satisfies the relationships Td≤Ts×1,000 and Td≤Tm×1,000, more preferably Td≤Ts×500 and Td≤Tm×500.

In another preferable aspect of the present disclosure, the device substrate 12 can have the function of supporting the three-layer structure. In this case, as shown in FIG. 3, the thickness Ts of the device substrate 12, the thickness Tm of the metal layer 14, and the thickness Td of the diamond layer 16 preferably satisfy the relationships Ts≥Tm×10 and Ts≥Td×10, more preferably Ts≥Tm×20 and Ts≥Td×20. The upper limit of Ts is not particularly limited but preferably satisfies the relationships Ts≤Tm×1,000 and Ts≤Td×1,000, more preferably Ts≤Tm×500 and Ts≤Td×500.

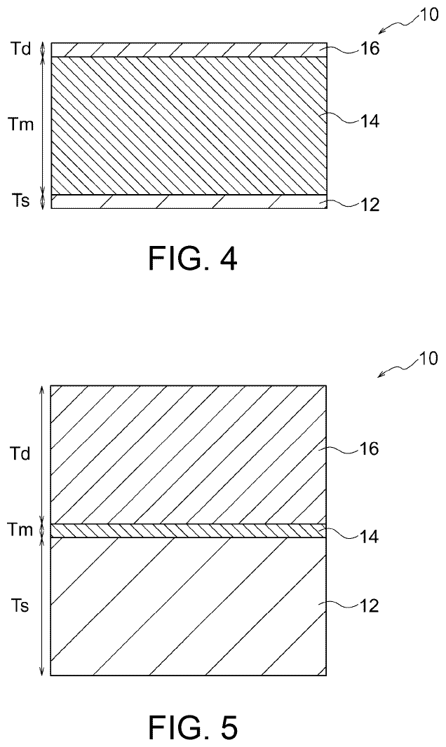

In still another preferable aspect of the present disclosure, the metal layer 14 can have the function of supporting the three-layer structure. In this case, as shown in FIG. 4, the thickness Ts of the device substrate 12, the thickness Tm of the metal layer 14, and the thickness Td of the diamond layer 16 preferably satisfy the relationships Tm≥Ts×10 and Tm≥Td×10, more preferably Tm≥Ts×20 and Tm≥Td×20. The upper limit of Td is not particularly limited but preferably satisfies the relationships Tm≤Ts×1,000 and Tm≤Td×1,000, more preferably Tm≤Ts×500 and Tm≤Td×500.

In still another preferable aspect of the present disclosure, both the device substrate 12 and the diamond layer 16 may have the function of supporting the three-layer structure. In this case, as shown in FIG. 5, the thickness Ts of the device substrate 12, the thickness Tm of the metal layer 14, and the thickness Td of the diamond layer 16 preferably satisfy the relationships Ts≥Tm×10 and Td≥Tm×10, more preferably Ts≥Tm×20 and Td≥Tm×20. The upper limits of Ts and Td are not particularly limited but preferably satisfy the relationships Ts≤Tm×1,000 and Td≤Tm×1,000, more preferably Ts≤Tm×500 and Td≤Tm×500.

The size of the laminated substrate 10 is not particularly limited, but, in the case where the laminated substrate 10 has a circular shape in a plan view, the diameter is preferably 2 cm or more, more preferably 5 cm or more, still more preferably 10 cm or more. The upper limit of the diameter is not particularly limited but is typically 300 cm or less. In the case where the laminated substrate 10 has a rectangular shape in a plan view, its size is preferably 2 cm or more×2 cm or more, more preferably 5 cm or more×5 cm or more, still more preferably 10 cm or more×10 cm or more. The upper limit of each side in this case is not particularly limited but is typically 300 cm or less×300 cm or less.

### EXAMPLES

### Example 1

A c-plane-oriented, double-side-polished GaN single crystal substrate with an off-angle of 0.2° (diameter: 50.8 mm, thickness: 0.45 mm) was provided as a device substrate. An iridium (Ir) film was grown on the N-face side of this device substrate. The deposition was performed by RF magnetron sputtering using metal Ir as the target under the conditions of an Ar gas pressure of 6×10⁻² Torr and a substrate temperature of 800° C. until the Ir film thickness reached 1.0 μm.

Biasing for diamond nucleation on the surface of the resulting Ir film of the substrate was performed by the following procedure. First, the substrate was set on an electrode (cathode) to which a negative voltage was applied of a biasing apparatus, and vacuum evacuation was performed. Subsequently, the substrate was heated to 800° C., then a 3-vol. % hydrogen-diluted methane gas was introduced, and biasing was performed at a pressure of 130 Torr. That is, a DC voltage was applied between both electrodes, and a predetermined DC current was applied.

Lastly, single crystal diamond was heteroepitaxially grown on the surface on the biased side by microwave plasma CVD at 1,000° C. for 30 hours.

The product removed from the CVD apparatus after the completion of the growth was a diamond/Ir/GaN laminated substrate without breaking. A section was observed, so that the thickness of the diamond film was found to be about 105 μm. From the results of the EBSD measurement, it was found that the diamond film was a biaxially oriented film oriented in terms of both the c-axis and the a-axis.

### Example 2

A c-plane-oriented, double-side-polished AlN single crystal substrate with an off-angle of 0.2° (diameter: 50.8 mm, thickness: 0.45 mm) was provided as a substrate for a device. On the N-face side of this substrate for a device, an Ir film and a diamond film were formed in order in the same manner as in Example 1. The product obtained was a diamond/Ir/AlN laminated substrate without breaking. A section was observed, so that the thickness of the diamond film was found to be about 105 μm. From the results of the EBSD measurement, it was found that the diamond film was a biaxially oriented film oriented in terms of both the c-axis and the a-axis.

### Example 3

A (111)-plane-oriented, double-side-polished Si single crystal substrate with no off-angle (diameter: 50.8 mm, thickness: 1 mm) was provided as a device substrate. A beryllium (Be) film was grown on one side of this device substrate. The deposition was performed by RF magnetron sputtering using metal Be as the target under the conditions of an Ar gas pressure of 1×10⁻² Torr and a substrate temperature of 750° C. until the Be film thickness reached 1.0 μm.

Biasing for diamond nucleation on the surface of the resulting Be film of the substrate was performed by the following procedure. First, the substrate was set on an electrode (cathode) to which a negative voltage was applied of a biasing apparatus, and vacuum evacuation was performed. Subsequently, the substrate was heated to 800° C., then a 3-vol. % hydrogen-diluted methane gas was introduced, and biasing was performed at a pressure of 130 Torr. That is, a DC voltage was applied between both electrodes, and a predetermined DC current was applied.

Lastly, single crystal diamond was heteroepitaxially grown on the surface on the biased side by microwave plasma CVD at 950° C. for 3 hours.

The product removed from the CVD apparatus after the completion of the growth was a diamond/Be/Si laminated substrate without breaking. A section was observed, so that the thickness of the diamond film was found to be about 8 μm. From the results of the EBSD measurement, it was found that the diamond film was a uniaxially oriented film oriented in terms of the c-axis.

### Example 4

A (111)-plane-oriented, double-side-polished 3C-SiC single crystal substrate with no off-angle (diameter: 50.8 mm, thickness: 0.35 mm) was provided as a device substrate. A beryllium (Be) film was grown on one side of this device substrate. The deposition was performed by RF magnetron sputtering using metal Be as the target under the conditions of an Ar gas of 1×10⁻² Torr and a substrate temperature of 750° C. until the Be film thickness reached 1.0 μm.

Biasing for diamond nucleation on the surface of the resulting Be film of the substrate was performed by the following procedure. First, the substrate was set on an electrode (cathode) to which a negative voltage was applied of a biasing apparatus, and vacuum evacuation was performed. Subsequently, the substrate was heated to 800° C., then a 3-vol. % hydrogen-diluted methane gas was introduced, and biasing was performed at a pressure of 130 Torr. That is, a DC voltage was applied between both electrodes, and a predetermined DC current was applied.

Lastly, single crystal diamond was heteroepitaxially grown on the surface on the biased side by microwave plasma CVD at 100° C. for 10 hours.

The product removed from the CVD apparatus after the completion of the growth was a diamond/Be/3C-SiC laminated substrate without breaking. A section was observed, so that the thickness of the diamond film was found to be about 30 μm. From the results of the EBSD measurement, it was found that the diamond film was a biaxially oriented film oriented in terms of both the c-axis and the a-axis.

### Example 5

A double-side-polished Z-cut LiTaO₃ single crystal substrate with no off-angle (diameter: 50.8 mm, thickness: 0.5 mm) was provided as a device substrate. On one side of this device substrate, an Ir film and a diamond film were formed in order in the same manner as in Example 1 except that the deposition time for the microwave plasma CVD was changed to 25 hours. The product obtained was a diamond/Ir/LiTaO₃ laminated substrate without breaking. A section was observed, so that the thickness of the diamond film was found to be about 90 μm. From the results of the EBSD measurement, it was found that the diamond film was a biaxially oriented film oriented in terms of both the c-axis and the a-axis.

### Example 6

A laminated substrate was produced in the same manner as in Example 1 except that the time for depositing the single crystal diamond by the microwave plasma CVD was changed to 150 hours. The thickness of the GaN layer of the resulting laminated substrate was reduced to 2 μm by polishing to provide a laminated substrate for a device.

The product was a diamond/Ir/GaN laminated substrate without breaking. A section was observed, so that the thickness of the diamond film was found to be about 300 μm. From the results of the EBSD measurement, it was found that the diamond film was a biaxially oriented film oriented in terms of both the c-axis and the a-axis.

What is claimed is:

1. A laminated substrate comprising a three-layer structure composed of:
a device substrate, which is composed of at least one single crystal material selected from the group consisting of Si, SiC, GaN, AlN, BN, Ga₂O₃, Cr₂O₃, LiTaO₃, and LiNbO₃;
a metal layer on the device substrate; and
a diamond layer on the metal layer.

2. The laminated substrate according to claim 1, wherein the device substrate is composed of at least one single crystal material selected from the group consisting of Si and SiC.

3. The laminated substrate according to claim 1, wherein the device substrate is composed of at least one single crystal material selected from the group consisting of GaN, AlN, and BN.

4. The laminated substrate according to claim 1, wherein the device substrate is composed of at least one single crystal material selected from the group consisting of Ga₂O₃, Cr₂O₃, LiTaO₃, and LiNbO_{3.}

5. The laminated substrate according to claim 1, wherein the metal layer is composed of a metal or alloy comprising at least one selected from the group consisting of Ir, Rh, Pt, Ru, and Au.

6. The laminated substrate according to claim 1, wherein the metal layer is composed of a metal or alloy comprising at least one selected from the group consisting of Ni, Cu, Fe, and Co.

7. The laminated substrate according to claim 1, wherein the metal layer is composed of a metal or alloy comprising Be.

8. The laminated substrate according to claim 1, wherein the metal layer is composed of a metal or alloy comprising Ir.

9. The laminated substrate according to claim 1, wherein the diamond layer is composed of a diamond single crystal.

10. The laminated substrate according to claim 1, wherein the diamond layer is composed of a biaxially oriented layer of diamond.

11. The laminated substrate according to claim 1, wherein the diamond layer is composed of a uniaxially oriented layer of diamond.

12. The laminated substrate according to claim 1, wherein the device substrate has a thickness of 1 μm to 30 μm.

13. The laminated substrate according to claim 1, wherein the metal layer has a thickness of 50 nm to 100 μm.

14. The laminated substrate according to claim 1, wherein the diamond layer has a thickness of 100 μm to 2.0 mm.

15. The laminated substrate according to claim 1, wherein a thickness Ts of the device substrate, a thickness Tm of the metal layer, and a thickness Td of the diamond layer satisfy relationships Td≥Ts×10 and Td≥Tm×10.

16. The laminated substrate according to claim 1, wherein a thickness Ts of the device substrate, a thickness Tm of the metal layer, and a thickness Td of the diamond layer satisfy relationships Ts≥Tm×10 and Ts≥Td×10.

17. The laminated substrate according to claim 1, wherein a thickness Ts of the device substrate, a thickness Tm of the metal layer, and a thickness Td of the diamond layer satisfy relationships Tm≥Ts×10 and Tm≥Td×10.

18. The laminated substrate according to claim 1, wherein a thickness Ts of the device substrate, a thickness Tm of the metal layer, and a thickness Td of the diamond layer satisfy relationships Ts≥Tm×10 and Td≥Tm×10.

19. The laminated substrate according to claim 1, wherein the metal layer is a film composed of a metal or alloy comprising Be deposited by sputtering.
